(19) United States
(12) Patent Application Publication
(10) Pub. No.: US 2012/0235177 A1
(43) Pub. Date: Sep. 20, 2012

(54) SEMICONDUCTOR LIGHT EMITTING DEVICE WAFER AND METHOD FOR MANUFACTURING SEMICONDUCTOR LIGHT EMITTING DEVICE

(75) Inventor: Tomomichi Naka, Kanagawa-ken (JP)

(73) Assignee: Kabushiki Kaisha Toshiba, Tokyo (JP)

(21) Appl. No.: 13/402,430

(22) Filed: Feb. 22, 2012

(30) Foreign Application Priority Data
Mar. 16, 2011 (JP) 2011-057938

(51) Int. Cl. H01L 33/50; H01L 27/15

(52) U.S. Cl. 257/88; 438/29; 257/E33.061; 257/E27.12

(57) ABSTRACT

According to one embodiment, a semiconductor light emitting device wafer includes a plurality of semiconductor light emitting devices, the plurality of semiconductor light emitting devices being collectively formed, and includes a light emitting unit and a wavelength conversion unit. The light emitting unit has a first major surface and a second major surface on a side opposite to the first major surface. The wavelength conversion unit is provided on the first major surface side. The wavelength conversion unit contains a fluorescer. A thickness of the wavelength conversion unit changes based on a distribution in a surface of the wafer of at least one selected from a wavelength and an intensity of light emitted from the light emitting unit of the plurality of semiconductor light emitting devices.

### CROSS-REFERENCE TO RELATED APPLICATIONS

This application is based upon and claims the benefit of priority from the prior Japanese Patent Application No. 2011-057938, filed on Mar. 16, 2011; the entire contents of which are incorporated herein by reference.

### FIELD

Embodiments described herein relate generally to a semiconductor light emitting device wafer and a method for manufacturing semiconductor light emitting device.

### BACKGROUND

There exist semiconductor light emitting devices in which a semiconductor light emitting element is combined with a member such as a fluorescer and the like that has a wavelength conversion effect. For example, there are semiconductor light emitting elements that use a group III nitride semiconductor such as gallium nitride (GaN), etc., to emit blue light having a high luminance. Then, white light can be emitted by combining the semiconductor light emitting element that emits the blue light with a wavelength conversion unit that includes a fluorescer capable of wavelength conversion. The wavelength conversion unit of such a semiconductor light emitting device that emits white light can be formed by simply coating or dropping a resin including the fluorescer capable of wavelength conversion onto a wafer on which the semiconductor light emitting element that emits the blue light is multiply formed and by curing the resin.

However, in the case where the wavelength of the light emitted from the light emitting unit provided in the semiconductor light emitting device fluctuates or the thickness of the resin including the fluorescer fluctuates, there is a risk that the chromaticity of the semiconductor light emitting device may fluctuate.

### BRIEF DESCRIPTION OF THE DRAWINGS

FIG. 1A to FIG. 1C are schematic views illustrating a semiconductor light emitting device wafer according to an embodiment of the invention;

FIG. 2 is a schematic cross-sectional view illustrating the semiconductor light emitting device according to this embodiment;

FIG. 3 is a schematic plan view illustrating an example of a wavelength distribution in the wafer surface of the light emitted from a light emitting unit;

FIG. 4 is a graph illustrating an example of the relationship between the wavelength of the light emitted from the light emitting unit and the chromaticity (Cy) of the light emitted from the semiconductor light emitting device;

FIG. 5 is a graph illustrating an example of the relationship between the thickness dimension of the wavelength conversion unit and the chromaticity (Cy) of the light emitted from the semiconductor light emitting device;

FIG. 6 is a graph illustrating an example of the relationship between the thickness dimension of the wavelength conversion unit and the diametrical-direction position in the wafer surface for a wavelength conversion unit formed by a method for manufacturing a semiconductor light emitting device according to a comparative example;

FIG. 7 is a flowchart illustrating the method for manufacturing the semiconductor light emitting device according to the embodiment of the invention;

FIG. 8A to FIG. 10D are schematic cross-sectional views illustrating the method for manufacturing the semiconductor light emitting device according to this embodiment;

FIG. 11 is a flowchart illustrating a method for manufacturing the semiconductor light emitting device according to another embodiment of the invention;

FIG. 12A to FIG. 12D are schematic cross-sectional views illustrating the method for manufacturing the semiconductor light emitting device according to this embodiment; and

FIG. 13A and FIG. 13B are schematic views illustrating the thickness dimension of the wavelength conversion unit formed by the method for manufacturing the semiconductor light emitting device according to this embodiment.

### DETAILED DESCRIPTION

According to one embodiment, a semiconductor light emitting device wafer includes a plurality of semiconductor light emitting devices, the plurality of semiconductor light emitting devices being collectively formed, and includes a light emitting unit and a wavelength conversion unit. The light emitting unit has a first major surface and a second major surface on a side opposite to the first major surface. The wavelength conversion unit is provided on the first major surface side. The wavelength conversion unit contains a fluorescer. A thickness of the wavelength conversion unit changes based on a distribution in a surface of the wafer of at least one selected from a wavelength and an intensity of light emitted from the light emitting unit of the plurality of semiconductor light emitting devices.

Embodiments of the invention will now be described with reference to the drawings. Similar components in the drawings are marked with like reference numerals, and a detailed description is omitted as appropriate.

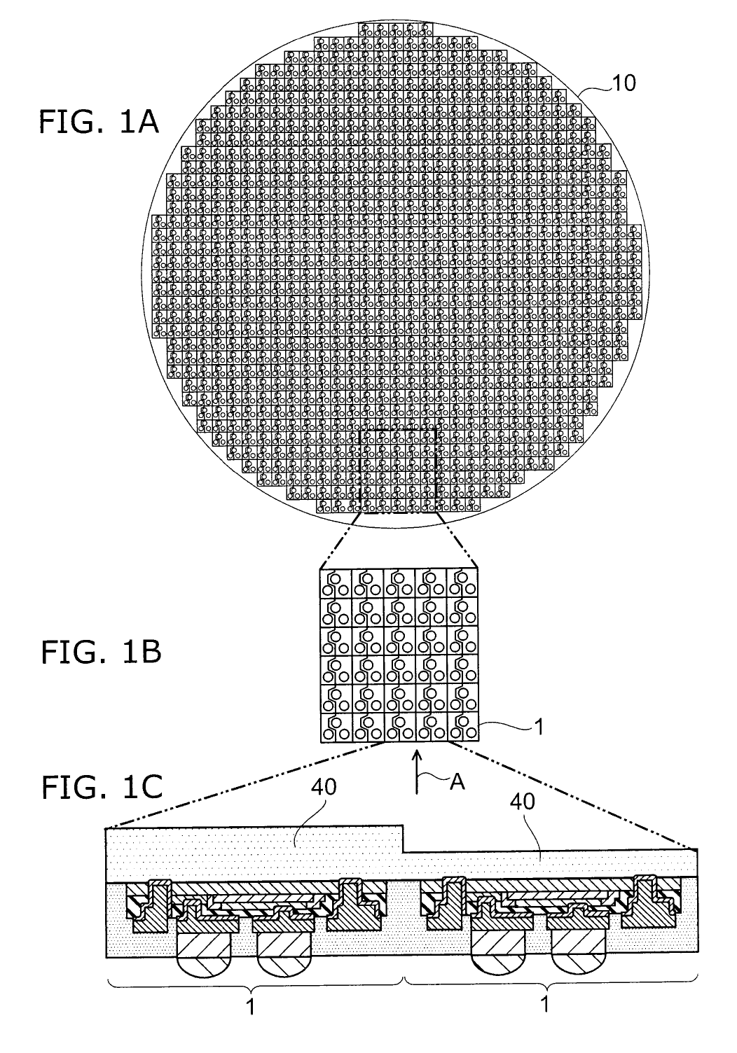

FIG. 1A to FIG. 1C are schematic views illustrating a semiconductor light emitting device wafer according to an embodiment of the invention.

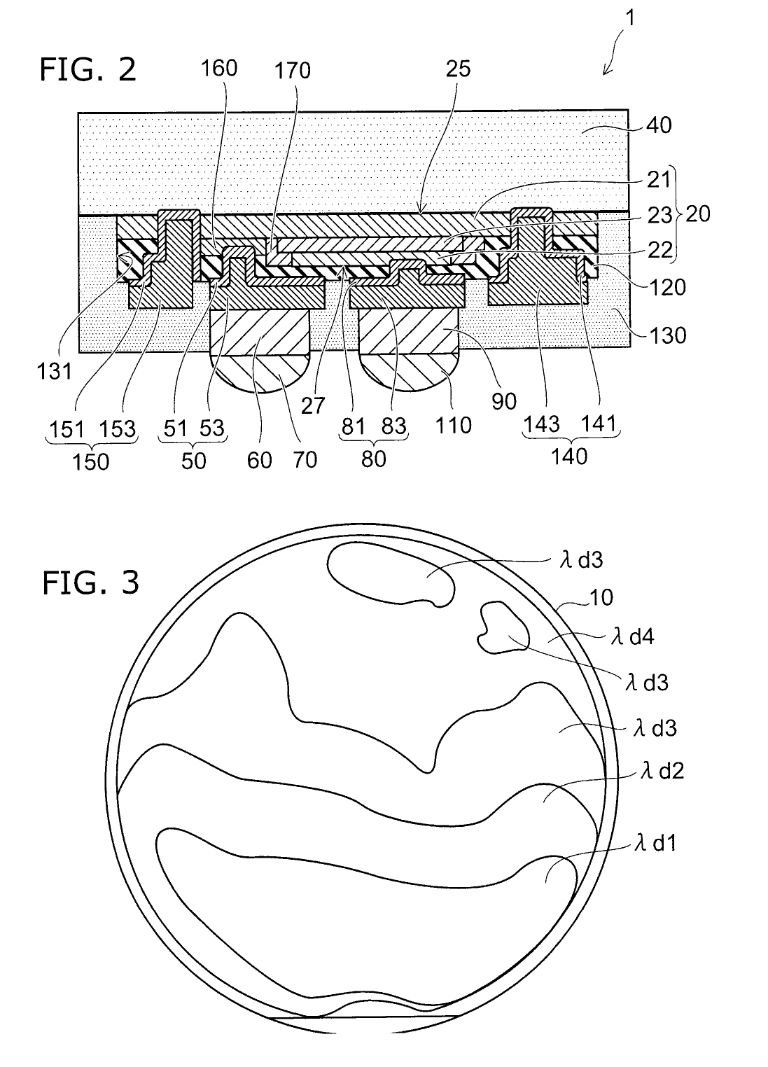

FIG. 2 is a schematic cross-sectional view illustrating the semiconductor light emitting device according to this embodiment.

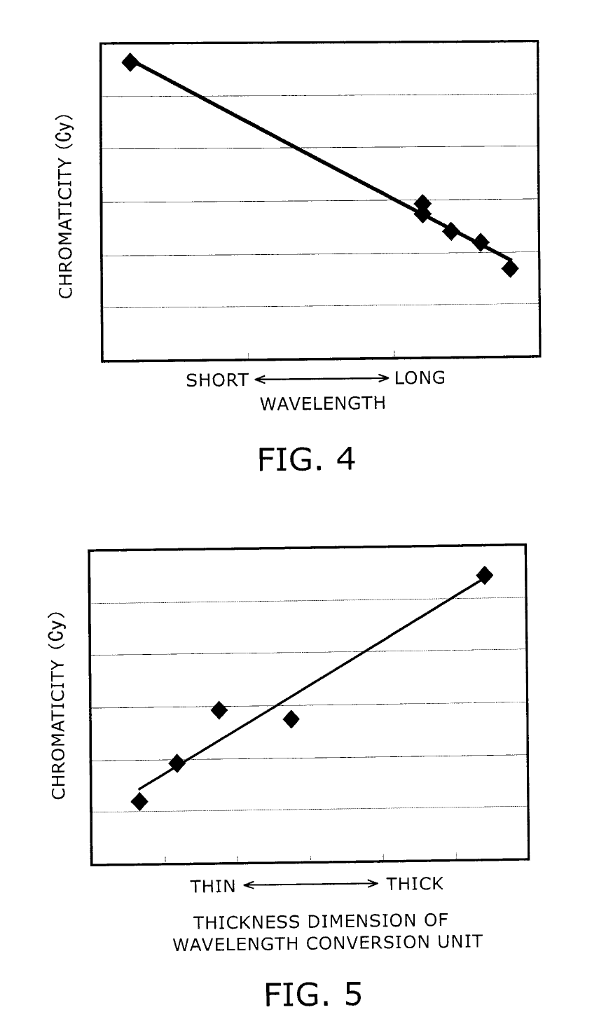

FIG. 3 is a schematic plan view illustrating an example of a wavelength distribution in the wafer surface of the light emitted from a light emitting unit.

FIG. 1A is a schematic plan view illustrating the semiconductor light emitting device wafer in which the multiple semiconductor light emitting devices are collectively formed. FIG. 1B is an enlarged schematic view illustrating an enlarged portion of the semiconductor light emitting device wafer. FIG. 1C is a schematic cross-sectional view illustrating two semiconductor light emitting devices of the semiconductor light emitting device wafer and is a schematic cross-sectional view illustrating the two semiconductor light emitting devices when viewed in the direction along arrow A illustrated in FIG. 1B.

In the method for manufacturing the semiconductor light emitting device 1 according to this embodiment as illustrated in FIG. 1A to FIG. 1C, the multiple semiconductor light emitting devices 1 are collectively formed, that is, formed integrally, on a semiconductor light emitting device wafer (hereinbelow also abbreviated as simply the wafer) 10 and subsequently singulated into the semiconductor light emitting devices 1. Thereby, the productivity of the semiconductor light emitting device 1 can be increased. It is possible for the semiconductor light emitting device 1 to be drastically smaller, thinner, and lighter than a conventional semiconductor light emitting device in which a semiconductor light emitting element is mounted in a package. The number of the multiple semiconductor light emitting devices 1 collectively formed on the wafer 10 is not limited to the number of the semiconductor light emitting devices 1 illustrated in FIG. 1A.

As illustrated in FIG. 2, the semiconductor light emitting device 1 according to this embodiment includes a light emitting unit 20, a wavelength conversion unit 40, a first electrode unit 50, a first conductive unit 60, a first connection member 70, a second electrode unit 80, a second conductive unit 90, a second connection member 110, an insulating unit 120, a sealing unit 130, a first interconnect unit 140, a second interconnect unit 150, a bonding unit 160, and an insulating unit 170.

The light emitting unit 20 includes a first semiconductor layer 21, a second semiconductor layer 22, and an active layer 23. The light emitting unit 20 has a first major surface 25 and a second major surface 27 on the side opposite to the first major surface 25.

In the case where the multiple light emitting units 20 are collectively formed on the wafer 10, there are cases where, for example, fluctuation of the composition, the thickness dimension, and the like of the active layer 23 occurs in the formation process. In the case where the fluctuation of the composition, the thickness dimension, and the like of the active layer 23 occurs, light emission characteristics such as the wavelength, the intensity, and the like of the light emitted from the light emitting unit 20 fluctuate. Therefore, as illustrated in FIG. 3, there are cases where the wavelength and the intensity of the light emitted from the light emitting unit 20 fluctuate in the surface of the wafer 10.

The contours of the wavelength of the light emitted from the multiple light emitting units 20 collectively formed on the wafer 10 are illustrated in the schematic plan view of FIG. 3. Wavelengths λd1, λd2, λd3, and λd4 illustrated in FIG. 3 have, for example, the relationship of the following Formula 1:

λd1<λd2<λd3<λd4 (1)

Thus, in the case where the wavelength of the light emitted from the light emitting unit 20 has a distribution in the surface of the wafer 10, fluctuation of the chromaticity of the white light emitted from the semiconductor light emitting device 1 occurs in the surface of the wafer 10 even in the case where the proportion of the fluorescer included in the wavelength conversion unit 40 is constant. Therefore, there are cases where it is difficult to increase the production output of good parts (the number of good parts or the yield) of the semiconductor light emitting devices 1 per wafer 10 surface.

Even in the case where the wavelength and the intensity of the light emitted from the multiple light emitting units 20 collectively formed on the wafer 10 is constant, or even in the case where the proportion of the fluorescer included in the wavelength conversion unit 40 is constant, the fluctuation of the chromaticity of the white light emitted from the semiconductor light emitting device 1 occurs in the surface of the wafer 10 when fluctuation of the thickness dimension of the wavelength conversion unit 40 occurs. Therefore, there are cases where it is difficult to increase the production output of good parts of the semiconductor light emitting devices 1 per wafer 10 surface. The relationship between the wavelength and the chromaticity of the light emitted from the light emitting unit 20 and the relationship between the thickness of the wavelength conversion unit 40 and the chromaticity is elaborated later.

Conversely, in the method for manufacturing the semiconductor light emitting device 1 according to this embodiment, the thickness of the wavelength conversion unit 40 is adjusted by adjusting the distance from a not-illustrated printing plate to a not-illustrated substrate, the first major surface 25 of the light emitting unit 20, or the second major surface 27 of the light emitting unit 20, where the not-illustrated printing plate is configured to be pressed onto, for example, the wavelength conversion unit 40 (the resin and the like into which a fluorescer is mixed) in the manufacturing process. Therefore, the fluctuation of the thickness dimension of the wavelength conversion unit 40 can be suppressed. Thereby, the fluctuation of the chromaticity of the white light in the surface of the wafer 10 can be suppressed. The production output of good parts of the semiconductor light emitting devices 1 per wafer 10 surface can be increased.

In the method for manufacturing the semiconductor light emitting device 1 according to this embodiment, the thickness of the wavelength conversion unit 40 of each of the multiple semiconductor light emitting devices 1 collectively formed on the wafer 10 is adjusted based on the wavelength, the intensity, and the like of the light emitted from the light emitting unit 20. For example, the thickness of the wavelength conversion unit 40 of each of the multiple semiconductor light emitting devices 1 collectively formed on the wafer 10 is adjusted based on the wavelength distribution illustrated in FIG. 3. Thereby, the fluctuation of the chromaticity of the white light in the surface of the wafer 10 can be suppressed. The production output of good parts of the semiconductor light emitting devices 1 per wafer 10 surface can be increased. In other words, according to this embodiment, there are cases where the thicknesses of the wavelength conversion units 40 of the multiple semiconductor light emitting devices 1 collectively formed on the wafer 10 are different from each other based on the wavelength and the like of the light emitted from the light emitting unit 20 as illustrated in FIG. 1C. The method for manufacturing the semiconductor light emitting device 1 according to this embodiment is elaborated later.

The semiconductor light emitting device 1 according to this embodiment will now be described further with reference to FIG. 2.

As described above, the light emitting unit 20 includes the first semiconductor layer 21, the second semiconductor layer 22, and the active layer 23. The light emitting unit 20 includes the first major surface 25 and the second major surface 27 on the side opposite to the first major surface 25.

The first semiconductor layer 21 is formed of, for example, an n-type nitride semiconductor and the like. The second semiconductor layer 22 is formed of, for example, a p-type nitride semiconductor and the like. Nitride semiconductors include, for example, GaN (gallium nitride), AlN (aluminum nitride), AlGaN (aluminum gallium nitride), InGaN (indium gallium nitride), etc.

The active layer 23 is provided between the first semiconductor layer 21 and the second semiconductor layer 22.

The active layer 23 may have, for example, a quantum well structure and the like that includes a well layer configured to produce light by the recombination of holes and electrons and a barrier layer (a clad layer) that has a larger bandgap than the well layer. In such a case, the active layer 23 may have a single quantum well (SQW) structure or a multiple quantum well (MQW) structure. The active layer 23 may have a structure in which multiple single quantum well structures are stacked.

The single quantum well structure may include, for example, a structure in which a barrier layer including GaN (gallium nitride), a well layer including InGaN (indium gallium nitride), and a barrier layer including GaN (gallium nitride) are stacked in this order.

The multiple quantum well structure may include, for example, a structure in which a barrier layer including GaN (gallium nitride), a well layer including InGaN (indium gallium nitride), a barrier layer including GaN (gallium nitride), a well layer including InGaN (indium gallium nitride), and a barrier layer including GaN (gallium nitride) are stacked in this order.

In such a case, the first semiconductor layer 21 may function as the barrier layer.

The active layer 23 is not limited to the quantum well structure and may appropriately have a structure capable of emitting light.

The materials of the first semiconductor layer 21, the second semiconductor layer 22, and the active layer 23 are not limited to nitride semiconductors; and other various semiconductor materials can be used.

The light emitting unit 20 is, for example, a light emitting diode and the like that has a peak light emission wavelength of about 380 nm to 530 nm. The light emitting unit 20 may be, for example, a light emitting diode and the like having a bandwidth of the light emission wavelength of about 350 nm to 600 nm. Alternatively, the light emission wavelength of the light emitting unit 20 may be longer than 600 nm.

The wavelength conversion unit 40 is provided on the first major surface 25 side of the light emitting unit 20. The wavelength conversion unit 40 includes, for example, a fluorescer that is capable of wavelength conversion and a medium mixed with the fluorescer. An organic material such as a resin and the like and an inorganic material such as glass and the like may be used as the medium. The fluorescer has, for example, a particle configuration.

The wavelength conversion unit 40 includes, for example, at least one fluorescer selected from fluorescers having peak light emission wavelengths at not less than 440 nm and not more than 470 nm (blue), not less than 500 nm and not more than 555 nm (green), not less than 560 nm and not more than 580 nm (yellow), and not less than 600 nm and not more than 670 nm (red). Alternatively, the wavelength conversion unit 40 includes, for example, a fluorescer having a bandwidth of the light emission wavelength of 380 nm to 720 nm.

The fluorescer includes, for example, at least one element selected from the group consisting of silicon (Si), aluminum (Al), titanium (Ti), germanium (Ge), phosphorus (P), boron (B), yttrium (Y), an alkaline earth element, a sulfide element, a rare-earth element, and a nitride element.

Materials of the fluorescer configured to emit the red fluorescence are, for example, as follows. However, the fluorescer configured to emit the red fluorescence of the embodiments is not limited to the following:

Y₂O₂S:Eu

Y₂O₂S:Eu+pigment

Y₂O₃:Eu

Zn₃(PO₄)₂:Mn

(Zn, Cd)S:Ag+In₂O₃

(Y, Gd, Eu)BO₃

(Y, Gd, Eu)₂O₃

YVO₄:Eu

La₂O₂S:Eu, Sm

LaSi₃N₅:Eu²⁺

α-sialon:Eu²⁺

CaAlSiN₃:Eu²⁺

CaSiNₓ:Eu²⁺

CaSiNₓ:Ce²⁺

M₂Si₅N₈Eu²⁺

CaAlSiN₃:Eu²⁺

(SrCa)AlSiN₃:Eu^{x+}

Srₓ(Si_{y}Al₃)_{z}(OₓN):Eu^{x+}

Materials of the fluorescer configured to emit the green fluorescence are, for example, as follows. However, the fluorescer configured to emit the green fluorescence of the embodiments is not limited to the following:

ZnS:Cu, Al

ZnS:Cu, Al+pigment

(Zn, Cd)S:Cu, Al

ZnS:Cu, Au, Al, +pigment

Y₃Al₅O₁₂:Tb

Y₃(Al, Ga)₅O₁₂:Tb

Y₂SiO₅:Tb

Zn₂SiO₄:Mn

(Zn, Cd)S:Cu

ZnS:Cu

Zn₂SiO₄:Mn

ZnS:Cu+Zn₂SiO₄:Mn

Gd₂O₂S:Tb

(Zn, Cd)S:Ag

ZnS:Cu, Al

Y₂O₂S:Tb

ZnS:Cu, Al+In₂O₃

(Zn, Cd)S:Ag+In₂O₃

(Zn, Mn)₂SiO₄

BaAl₁₂O₁₉:Mn

(Ba, Sr, Mg)O.aAl₂O₃:Mn

LaPO₄:Ce, Tb

Zn₂SiO₄:Mn

ZnS:Cu

3(Ba, Mg, Eu, Mn)O.8Al₂O₃

La₂O₃.0.2SiO₂.0.9P₂O₅:Ce,Tb

CeMgAl₁₁O₁₉:Tb

CaSc₂O₄:Ce

(BrSr)SiO₄:Eu

α-sialon:Yb²⁺

β-sialon:Eu²⁺

(SrBa)YSi₄N₇:Eu²⁺

(CaSr)Si₂O₄N₇:Eu²⁺

Sr(SiAl)(ON):Ce

Materials of the fluorescer configured to emit the blue fluorescence are, for example, as follows. However, the fluorescer configured to emit the blue fluorescence of the embodiments is not limited to the following:

ZnS:Ag

ZnS:Ag+pigment

ZnS:Ag, Al

ZnS:Ag, Cu, Ga, Cl

ZnS:Ag+In₂O₃

ZnS:Zn+In₂O₃

(Ba, Eu)MgAl₁₀O₁₇

(Sr, Ca, Ba, Mg)₁₀(PO₄)6Cl₂:Eu

Sr₁₀(PO₄)6Cl₂:Eu

(Ba, Sr, Eu)(Mg, Mn)Al₁₀O₁₇

10(Sr, Ca, Ba, Eu).6PO₄.Cl₂

BaMg₂Al₁₆O₂₅:Eu

Materials of the fluorescer configured to emit the yellow fluorescence are, for example, as follows. However, the fluorescer configured to emit the yellow fluorescence of the embodiments is not limited to the following:

Li(Eu, Sm)W₂O₈

(Y, Gd)₃, (Al, Ga)₅O₁₂:Ce³⁺

Li₂SrSiO₄:Eu²⁺

(Sr(Ca, Ba))₃SiO₅:Eu²⁺

SrSi₂ON_{2.7}:Eu²⁺

Materials of the fluorescer configured to emit the yellowish green fluorescence are, for example, as follows. However, the fluorescer configured to emit the yellowish green fluorescence of the embodiments is not limited to the following:

SrSi₂ON_{2.7}:Eu²⁺

As the mixing ratio of the fluorescer is reduced, the color tone approaches blue (near a color temperature of 10000 K); and as the mixing ratio of the fluorescer is increased, the color tone approaches yellow (a color temperature of 6500 K to 2800 K). It is unnecessary for the mixed fluorescer to be of one type; and multiple types of fluorescers may be mixed. For example, the fluorescer configured to emit the red fluorescence, the fluorescer configured to emit the green fluorescence, the fluorescer configured to emit the blue fluorescence, the fluorescer configured to emit the yellow fluorescence, and the fluorescer configured to emit the yellowish green fluorescence may be mixed. The mixture proportion of the multiple types of fluorescers may be changed to change the tint of the light to be white light with a blue tint, white light with a yellow tint, etc.

The resin into which the fluorescer is mixed may include, for example, an epoxy resin, a silicone-based resin, a methacrylic resin (PMMA), polycarbonate (PC), cyclic polyolefin (COP), alicyclic acrylic (OZ), allyl diglycol carbonate (ADC), an acrylic resin, a fluorocarbon resin, a hybrid resin of a silicone-based resin and an epoxy resin, a urethane resin, etc. It is more favorable for the refractive index of the resin into which the fluorescer is mixed to be not greater than the refractive index of the fluorescer. It is more favorable for the transmittance of the resin with respect to the light emitted from the light emitting unit 20 to be not less than 90%.

There is a risk that the resin of the wavelength conversion unit 40 may degrade in the case where the light emitted from the light emitting unit 20 has a short wavelength from ultraviolet to blue and the luminance of the light emitted from the light emitting unit 20 is high. Therefore, it is more favorable for the resin of the wavelength conversion unit 40 to have the property of not degrading easily due to blue light and the like. Resins that do not degrade easily due to blue light and the like may include, for example, methyl phenyl silicone, dimethyl silicone, a hybrid resin of methyl phenyl silicone and an epoxy resin, etc., having a refractive index of about 1.5. However, the resin into which the fluorescer is mixed is not limited to those illustrated and may be modified appropriately. An organic substance such as a saccharide and an inorganic substance such as glass and the like may be used instead of the resin.

The first electrode unit 50 includes a bonding unit 51 and a conductive unit 53. The conductive unit 53 is electrically connected to the first semiconductor layer 21 via the bonding unit 51 and the bonding unit 160. The bonding unit 51 includes, for example, a double layer of Ni (nickel)/Au (gold). In such a case, for example, the thickness dimension of Ni (nickel) layer is about 1 μm; and the thickness dimension of the Au (gold) layer is about 1 μm. The conductive unit 53 is formed of, for example, Cu (copper) and the like. The materials and the thickness dimensions of the bonding unit 51 and the conductive unit 53 are not limited to those illustrated and may be modified appropriately.

The first conductive unit 60 is provided to pierce from the bottom surface of a recess 131 of the sealing unit 130 to the end surface of the sealing unit 130. For example, the first conductive unit 60 has a circular columnar configuration and is formed of a metal material such as Cu (copper), etc. One end portion of the first conductive unit 60 is electrically connected to the conductive unit 53. Thereby, the first conductive unit 60 is electrically connected to the first semiconductor layer 21 via the first electrode unit 50. The configuration, the material, and the like of the first conductive unit 60 are not limited to those illustrated and may be modified appropriately.

The first connection member 70 is provided to cover the end surface of the first conductive unit 60 exposed from the sealing unit 130. The first connection member 70 is, for example, a so-called solder bump and the like. In the case where the first connection member 70 is a solder bump, the configuration of the first connection member 70 is, for example, hemispherical; and the material of the first connection member 70 is, for example, a solder material used in surface mounting. In such a case, the solder material used in the surface mounting may include, for example, Sn-3.0Ag-0.5Cu solder, Sn-0.8Cu solder, Sn-3.5Ag solder, etc.

The configuration, the material, and the like of the first connection member 70 are not limited to those illustrated and may be modified appropriately according to the method for mounting the semiconductor light emitting device 1 and the like. The first connection member 70 may have, for example, a thin-film configuration and may include, for example, a double layer of Ni (nickel)/Au (gold). The first connection member 70 is not always necessary and may be appropriately provided according to the method for mounting the semiconductor light emitting device 1 and the like.

The second electrode unit 80 includes a bonding unit 81 and a conductive unit 83. The conductive unit 83 is electrically connected to the second semiconductor layer 22 via the bonding unit 81. The configurations, the structures, the materials, and the like of the bonding unit 81 and the conductive unit 83 are similar to those of the configurations, the structures, the materials, and the like of the bonding unit 51 and the conductive unit 53 described above.

The second conductive unit 90 is provided to pierce from the bottom surface of the recess 131 of the sealing unit 130 to the end surface of the sealing unit 130. One end portion of the second conductive unit 90 is electrically connected to the conductive unit 83. Thereby, the second conductive unit 90 is electrically connected to the second semiconductor layer 22 via the second electrode unit 80. The configuration, the structure, the material, and the like of the second conductive unit 90 are similar to the configuration, the structure, the material, and the like of the first conductive unit 60 described above.

The second connection member 110 is provided to cover the end surface of the second conductive unit 90 exposed from the sealing unit 130. The configuration, the structure, the material, and the like of the second connection member 110 are similar to the configuration, the structure, the material, and the like of the first connection member 70 described above. Similarly to the first connection member 70, the second connection member 110 is not always necessary and may be appropriately provided according to the method for mounting the semiconductor light emitting device 1 and the like.

The insulating unit 120 is provided to fill the recess 131 provided in the sealing unit 130. The insulating unit 120 is formed from an insulating material. For example, the insulating unit 120 is formed from an inorganic material such as SiO₂, a resin, and the like. In such a case, there is a risk that the resin of the insulating unit 120 may degrade in the case where the light emitted from the light emitting unit 20 has a short wavelength from ultraviolet to blue light and the luminance of the light emitted from the light emitting unit 20 is high. Therefore, it is more favorable for the resin of the insulating unit 120 to have the property of not degrading easily due to the blue light and the like in the case where the insulating unit 120 is formed from the resin. Resins that do not degrade easily due to the blue light and the like may include, for example, methyl phenyl silicone, dimethyl silicone, and the like having a refractive index of about 1.5.

The sealing unit 130 is provided on the second major surface 27 side to seal the first conductive unit 60 and the second conductive unit 90 while leaving the end portion of the first conductive unit 60 and the end portion of the second conductive unit 90 exposed. The sealing unit 130 is formed from, for example, a thermosetting resin and the like. The sealing unit 130 performs the role of sealing the light emitting unit 20, the first electrode unit 50, and the second electrode unit 80. The sealing unit 130 and the insulating unit 120 may be formed integrally.

The first interconnect unit 140 includes a bonding unit 141 and a conductive unit 143. The conductive unit 143 is electrically connected to the first semiconductor layer 21 via the bonding unit 141. The configurations, the structures, the materials, and the like of the bonding unit 141 and the conductive unit 143 are similar to the configurations, the structures, the materials, and the like of the bonding unit 51 and the conductive unit 53 described above, respectively. The first interconnect unit 140 is not always necessary and may be appropriately provided if necessary.

The second interconnect unit 150 includes a bonding unit 151 and a conductive unit 153. The conductive unit 153 is electrically connected to the first semiconductor layer 21 via the bonding unit 151. The configurations, the structures, the materials, and the like of the bonding unit 151 and the conductive unit 153 may be similar to the configurations, the structures, the materials, and the like of the bonding unit 51 and the conductive unit 53 described above, respectively. Similarly to the first interconnect unit 140, the second interconnect unit 150 is not always necessary and may be appropriately provided if necessary.

The bonding unit 160 is provided between the first electrode unit 50 and the first semiconductor layer 21. The bonding unit 160 is formed of, for example, Cu (copper) and the like. The bonding unit 160 is not always necessary and may be appropriately provided if necessary.

The insulating unit 170 is provided to cover the side surfaces of the active layer 23 and the second semiconductor layer 22. The insulating unit 170 is formed from an insulating material. The material properties of the insulating unit 170 are, for example, the same as those of the material of the insulating unit 120. The insulating unit 170 and the insulating unit 120 may be formed integrally.

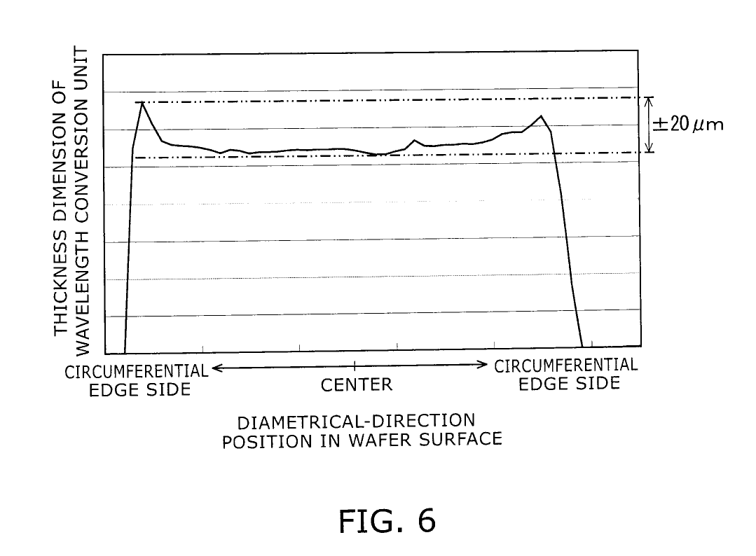

FIG. 4 is a graph illustrating an example of the relationship between the wavelength of the light emitted from the light emitting unit and the chromaticity (Cy) of the light emitted from the semiconductor light emitting device.

Here, the case is illustrated where the light emitting unit 20 emits blue light and a fluorescer configured to emit green light by absorbing the blue light and a fluorescer configured to emit red light by absorbing the blue light are dispersed in the wavelength conversion unit 40. In other words, a white light in which the red light, the green light, and the blue light are mixed is emitted from the semiconductor light emitting device. The vertical axis of FIG. 4 illustrates the chromaticity (Cy) of this white light.

The light emitting unit 20 is formed using, for example, epitaxial growth and the like. As described above in regard to FIG. 1A to FIG. 3, there are cases where, for example, fluctuation of the composition and the thickness dimension of the active layer 23 occurs in the formation process in the case where the multiple light emitting units 20 are collectively formed on the wafer 10. In the case where the fluctuation of the composition and the thickness dimension of the active layer 23 occurs, the light emission characteristics of the wavelength, the intensity, and the like of the light emitted from the light emitting unit 20 fluctuate. In such a case, the balance of the red light, the green light, and the blue light emitted from the semiconductor light emitting device undesirably changes if the amount of the fluorescer included in the wavelength conversion unit 40 is constant. In other words, as illustrated in FIG. 4, the chromaticity of the white light undesirably changes according to the change of the wavelength and the intensity of the light emitted from the light emitting unit 20.

According to experimental results such as those illustrated in FIG. 4, a change ΔCy of a chromaticity Cy of the white light emitted from the semiconductor light emitting device 1 is about 0.015 in the case where a change Δλd of a wavelength λd of the light emitted from the light emitting unit 20 is about 1.0 nm (nanometers). According to knowledge obtained by the inventor, there is a risk that chromaticity shift (uneven color) may be perceived by human vision in the case where the change ΔCy of the chromaticity Cy of the white light exceeds 0.015.

Conversely, according to the method for manufacturing the semiconductor light emitting device 1 according to this embodiment, the thickness of the wavelength conversion unit 40 is adjusted based on the wavelength and the intensity of the light emitted from the light emitting unit 20 even in the case where, for example, the wavelength and the intensity of the light emitted from the light emitting unit 20 fluctuate in the surface of the wafer 10 due to the fluctuation of the composition and the thickness dimension of the active layer 23. That is, the thicknesses of the wavelength conversion units 40 of the multiple semiconductor light emitting devices 1 collectively formed on the wafer 10 are adjusted based on the wavelength distribution in the surface of the wafer 10 of the light emitted from the light emitting unit 20. Thereby, the fluctuation of the chromaticity of the white light in the surface of the wafer 10 can be suppressed; and the chromaticity shift in the surface of the wafer 10 can be suppressed. The production output of good parts of the semiconductor light emitting devices 1 per wafer 10 surface can be increased.

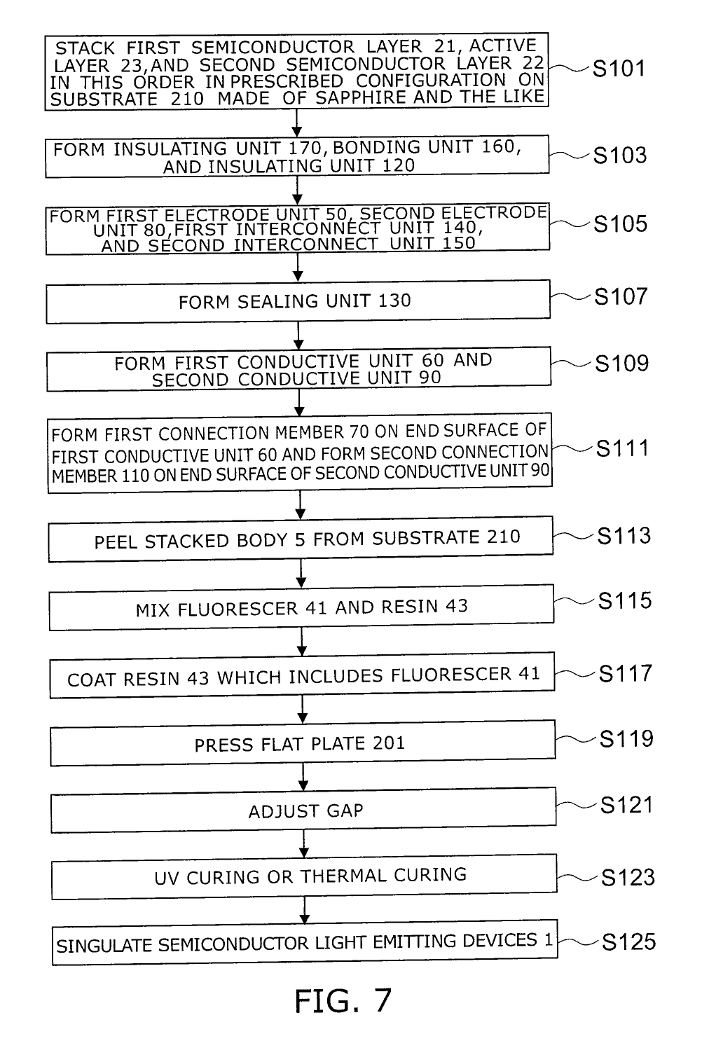

FIG. 5 is a graph illustrating an example of the relationship between the thickness dimension of the wavelength conversion unit and the chromaticity (Cy) of the light emitted from the semiconductor light emitting device.

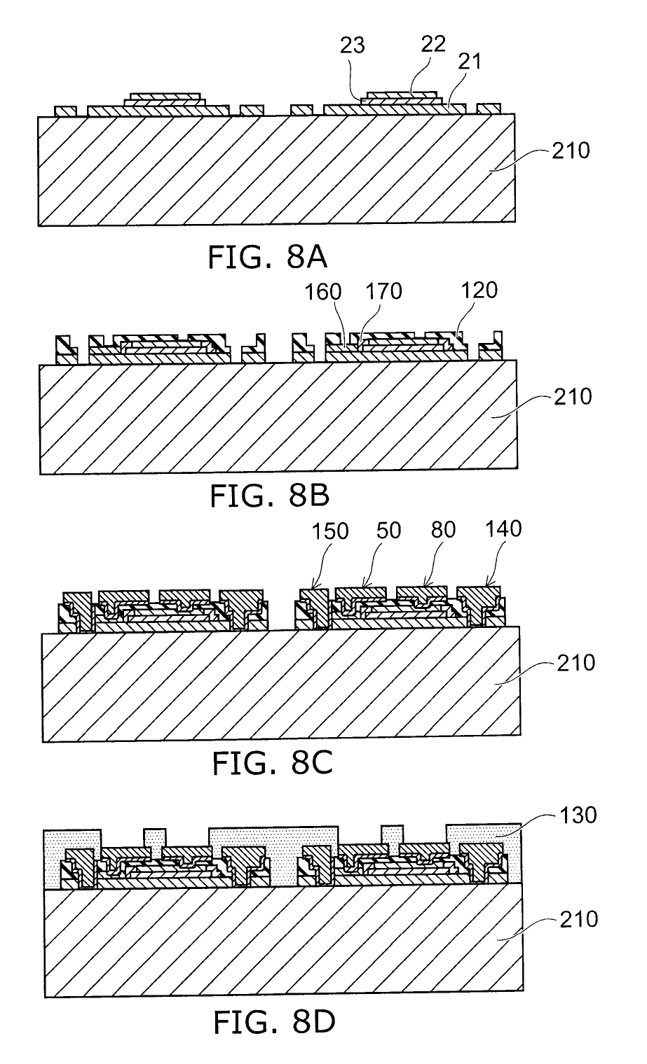

FIG. 6 is a graph illustrating an example of the relationship between the thickness dimension of the wavelength conversion unit and the diametrical-direction position in the wafer surface for a wavelength conversion unit formed by a method for manufacturing a semiconductor light emitting device according to a comparative example.

The fluorescer dispersed in the wavelength conversion unit 40 is as described above in regard to FIG. 4. That is, the vertical axis of FIG. 5 illustrates the chromaticity (Cy) of the white light.

As illustrated in FIG. 5, the chromaticity of the white light changes as the thickness dimension of the wavelength conversion unit 40 changes even in the case where the wavelength and the intensity of the light emitted from the multiple light emitting units 20 collectively formed on the wafer 10 are constant or even in the case where the proportion of the fluorescer included in the wavelength conversion unit 40 is constant. According to experimental results such as those illustrated in FIG. 5, the change ΔCy of the chromaticity Cy of the white light emitted from the semiconductor light emitting device 1 is about 0.015 in the case where the change of the thickness dimension of the wavelength conversion unit 40 is about 15 μm (micrometers). Therefore, the fluctuation of the chromaticity of the white light occurs in the surface of the wafer 10 when the fluctuation of the thickness dimension of the wavelength conversion unit 40 occurs even in the case where the wavelength and the intensity of the light emitted from the multiple light emitting units 20 collectively formed on the wafer 10 are constant or even in the case where the proportion of the fluorescer included in the wavelength conversion unit 40 is constant.

As illustrated in FIG. 6, the thickness dimension of the wavelength conversion unit formed by the method for manufacturing the semiconductor light emitting device according to the comparative example has fluctuation in the surface of the wafer of about ±20 μm. Therefore, the change ΔCy of the chromaticity Cy of the white light emitted from the semiconductor light emitting device collectively formed using the method for manufacturing the semiconductor light emitting device according to the comparative example is larger than 0.015. Thereby, there is a risk that the chromaticity shift may be perceived by human vision.

Conversely, according to the method for manufacturing the semiconductor light emitting device 1 according to this embodiment, the thickness of the wavelength conversion unit 40 is adjusted by adjusting the distance from, for example, a not-illustrated printing plate to a not-illustrated substrate, the first major surface 25 of the light emitting unit 20, or the second major surface 27 of the light emitting unit 20 in the manufacturing process, where the not-illustrated printing plate is configured to be pressed onto the wavelength conversion unit 40. Therefore, the fluctuation of the thickness dimension of the wavelength conversion unit 40 can be adjusted. Thereby, the fluctuation of the chromaticity of the white light in the surface of the wafer 10 can be suppressed; and the chromaticity shift in the surface of the wafer 10 can be suppressed. The production output of good parts of the semiconductor light emitting devices 1 per wafer 10 surface can be increased.

The method for manufacturing the semiconductor light emitting device according to the embodiment of the invention will now be described with reference to the drawings.

First, the method for manufacturing will be described in which the thickness of the wavelength conversion unit 40 is adjusted by adjusting the distance from the printing plate to the substrate, the first major surface 25 of the light emitting unit 20, or the second major surface 27 of the light emitting unit 20 in the manufacturing process, where the printing plate is configured to be pressed onto the wavelength conversion unit 40 (the resin in which the fluorescer is mixed).

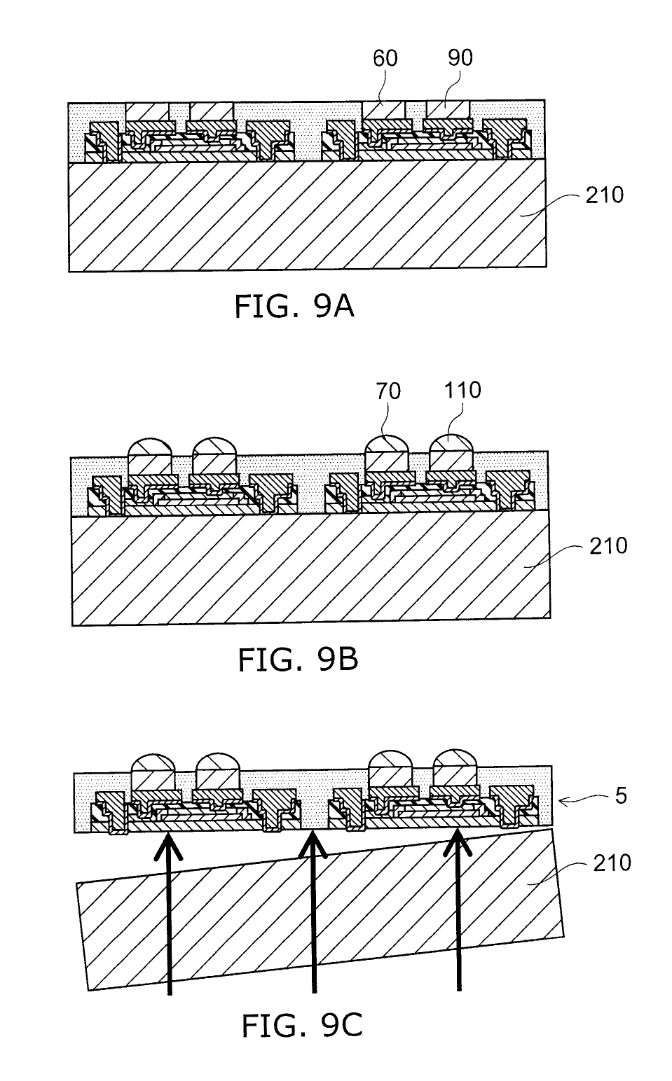

FIG. 7 is a flowchart illustrating the method for manufacturing the semiconductor light emitting device according to the embodiment of the invention.

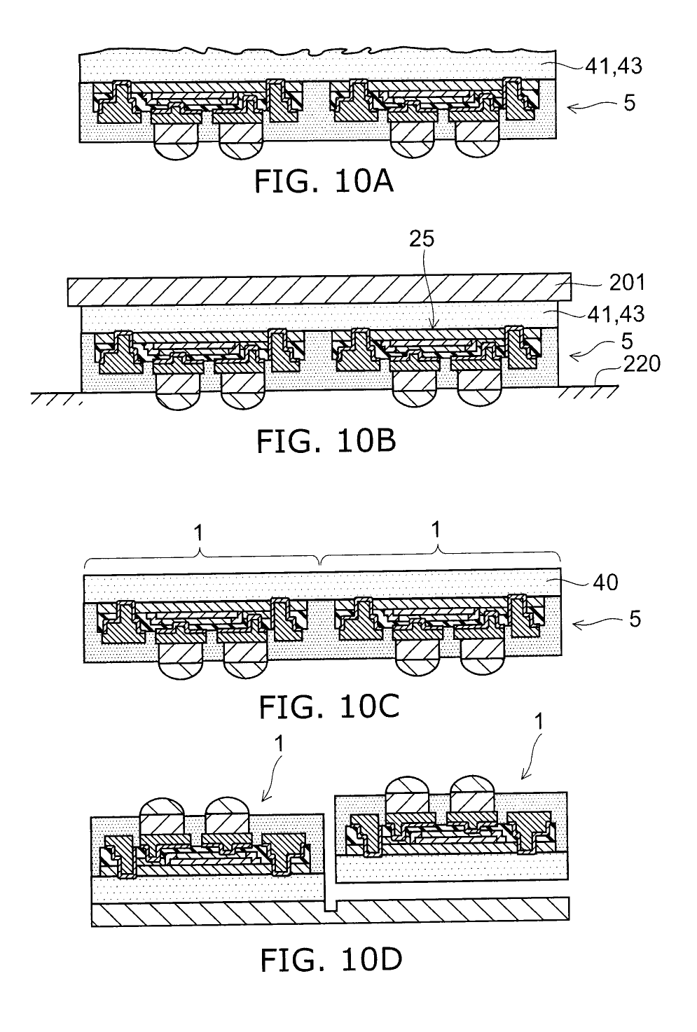

FIG. 8A to FIG. 10D are schematic cross-sectional views illustrating the method for manufacturing the semiconductor light emitting device according to this embodiment.

First, as illustrated in FIG. 8A, the first semiconductor layer 21, the active layer 23, and the second semiconductor layer 22 are stacked in this order in a prescribed configuration on a substrate 210 formed of sapphire and the like (step S101). In such a case, the stacking of these layers can be performed using vapor deposition and the like. The vapor deposition may include, for example, metal organic chemical vapor deposition (MOCVD), hydride vapor phase epitaxy (HVPE), molecular beam epitaxy (MBE), and the like.

Then, the first semiconductor layer 21, the active layer 23, and the second semiconductor layer 22 are appropriately patterned to correspond to the light emitting unit included in each of the multiple semiconductor light emitting devices. The patterning may be executed using lithography, etching, and the like.

Thus, the multiple light emitting units 20 (referring to FIG. 2) are collectively formed on the wafer.

Then, as illustrated in FIG. 8B, the insulating unit 170, the bonding unit 160, and the insulating unit 120 are formed (step S103). In such a case, the insulating unit 170, the bonding unit 160, and the insulating unit 120 may be formed by combining lithography, etching, and the like with various physical vapor deposition (PVD) methods such as vacuum vapor deposition and sputtering, various chemical vapor deposition (CVD) methods, and the like.

Continuing as illustrated in FIG. 8C, the first electrode unit 50, the second electrode unit 80, the first interconnect unit 140, and the second interconnect unit 150 are formed (step S105). Then, as illustrated in FIG. 8D, the sealing unit 130 is formed (step S107). The methods for forming the first electrode unit 50, the second electrode unit 80, the first interconnect unit 140, the second interconnect unit 150, and the sealing unit 130 may include, for example, the formation methods described above in regard to step S103 and the like.

Then, as illustrated in FIG. 9A, the first conductive unit 60 and the second conductive unit 90 are formed (step S109). In such a case, other than the formation methods described above in regard to step S103, the first conductive unit 60 and the second conductive unit 90 may be formed by combining plating and the like with lithography, etching, and the like.

Continuing as illustrated in FIG. 9B, the first connection member 70 is formed on the end surface of the first conductive unit 60; and the second connection member 110 is formed on the end surface of the second conductive unit 90 (step S111). The methods for forming the first connection member 70 and the second connection member 110 may include the formation methods described above in regard to step S109 and the like.

Then, as illustrated in FIG. 9C, the stacked body 5 thus formed is peeled from the substrate 210 (step S113). In such a case, the stacked body 5 may be peeled from the substrate 210 using laser lift-off and the like.

Here, according to this embodiment, the light emitting unit 20 (the first semiconductor layer 21, the active layer 23, and the second semiconductor layer 22) are peeled from the substrate 210 in the state of being supported by the sealing unit 130 made of resin and the conductive units 60 and 90 made of metal. Thereby, the light emitting unit 20 can be peeled from the substrate 210 while suppressing the stress applied to the light emitting unit 20.

In other words, in the case where a hard support body such as, for example, a silicon wafer, etc., is used to support the light emitting unit 20, problems occur where residual stress is applied and the semiconductor layer breaks or cracks after the removal.

Conversely, according to this embodiment, the stress applied to the light emitting unit 20 can be reduced by the light emitting unit 20 being supported by the flexible support body that includes the sealing unit 130 made of resin and the conductive units 60 and 90 made of metal. In other words, the residual stress occurring between the sealing unit 130, the conductive units 60 and 90, and the light emitting unit 20 is relatively small because the sealing unit 130 made of resin and the conductive units 60 and 90 made of metal plating layers are flexible and the metal is plated at substantially room temperature.

Conventionally, methods for separating semiconductor layers such as the light emitting unit 20 from the sapphire substrate include, for example, performing the separation by irradiating a laser after bonding a silicon substrate to the wafer using the Au—Sn solder at a high temperature not less than 300° C. However, in such conventional methods, a large residual stress remains between the sapphire substrate and the silicon substrate because the two substrates have different coefficients of thermal expansion, are rigid bodies, and are bonded at a high temperature. As a result, problems exist where the thin and brittle semiconductor layer (e.g., the light emitting unit 20) cracks because the residual stress is locally released from the separation portion when the separation is started by irradiating the laser.

Conversely, in this embodiment, discrepancies such as cracks and the like of the light emitting unit 20 do not occur and manufacturing is possible with high yields because the residual stress is small and the light emitting unit 20 is separated from the substrate 210 in the state of being supported by the flexible support body (the sealing unit 130 and the conductive units 60 and 90).

Such a unique operational effect is similarly obtained also in the case where the substrate 210 is removed using a method other than laser irradiation. For example, even in the case where the substrate 210 is removed using a method such as polishing, etching, and the like, it is substantially unrealistic for the substrate 210 to be removed or peeled uniformly and simultaneously over the entire wafer having a size of several inches or more.

That is, in the case where the substrate 210 is removed by polishing and in the case where the substrate 210 is removed by etching, the state occurs in which the substrate 210 disappears or is peeled first at only a portion of the wafer having a size of several inches or more.

In such a state as described above, the thin and brittle light emitting unit 20 undesirably cracks because the residual stress is locally released from the separation portion.

Conversely, according to this embodiment, the residual stress can be reduced by the light emitting unit 20 being supported by the flexible support body made of the sealing unit 130 and the conductive units 60 and 90. As a result, it is possible to remove the substrate while suppressing breakage and cracks even in the case where the substrate 210 is removed using methods such as polishing, etching, and the like.

Further, according to this embodiment, the multiple light emitting units 20 collectively formed on the wafer are isolated from each other. Thereby, the stress on the light emitting units 20 can be dispersed; and the cracks and the breakage can be suppressed more effectively. That is, in the case where the multiple light emitting units 20 are formed mutually continuously, the stress and the distortion are not dispersed and the cracks and the breakage occur easily in the continuous body of the light emitting unit 20 when peeling the substrate 210. Conversely, according to this embodiment, the cracks and the breakage can be effectively suppressed because the stress and the distortion are dispersed by the multiple light emitting units 20 being isolated from each other and the stress and the distortion of the light emitting units 20 are reduced by the stress and the distortion being absorbed by the sealing unit 130 formed between the light emitting units 20.

Thus, after the substrate 210 is peeled, a fluorescer 41 and a resin 43 of the wavelength conversion unit 40 are mixed (step S115). Continuing as illustrated in FIG. 10A, the resin 43 into which the fluorescer 41 is mixed with a prescribed proportion is coated onto the first major surface 25 side of the light emitting unit 20 (step S117). In such a case, the resin 43 into which the fluorescer 41 is mixed may be coated using printing, coating, and the like such as squeegee, screen printing, spin coating, etc. FIG. 10A illustrates the state in which the peeled stacked body 5 is inverted.

Then, as illustrated in FIG. 10B, a flat plate (a printing plate) 201 is pressed onto the resin 43 (including the fluorescer 41) coated onto the first major surface 25 side of the light emitting unit 20 (step S119). The flat plate 201 is formed of metal, quartz, or a transparent resin. The transparent resin is a resin capable of transmitting at least UV of a wavelength not more than 405 nm. Then, the thickness of the resin 43 into which the fluorescer 41 is mixed is adjusted to the target thickness by adjusting the distance from the flat plate 201 to the first major surface 25 of the light emitting unit 20 (step S121). Alternatively, for example, the thickness of the resin 43 into which the fluorescer 41 is mixed is adjusted to the target thickness by adjusting the distance from the flat plate 201 to a substrate 220 on which the stacked body 5 is placed (step S121). Alternatively, the thickness of the resin 43 into which the fluorescer 41 is mixed may be adjusted to the target thickness by adjusting the distance from the flat plate 201 to a major surface or substrate that is different from the first major surface 25 and the substrate 220.

Then, the wavelength conversion unit 40 is formed by curing the resin 43 including the fluorescer 41 by irradiating ultraviolet (UV) onto the resin 43 including the fluorescer 41 or by heating the resin 43 including the fluorescer 41 (step S123). In the case of the curing by irradiating the ultraviolet, the resin 43 is, for example, an ultraviolet-curing resin. On the other hand, in the case of the curing by heating, the resin 43 is, for example, a thermosetting resin.

Continuing as illustrated in FIG. 10C, the flat plate 201 is peeled from the collectively-formed multiple semiconductor light emitting devices 1.

Then, as illustrated in FIG. 10D, the semiconductor light emitting devices 1 are singulated (step S125). In other words, the method for manufacturing the semiconductor light emitting device 1 according to this embodiment includes a process of integrally forming (collectively forming) the multiple semiconductor light emitting devices 1 and a process of singulating the integrally-formed (collectively-formed) multiple semiconductor light emitting devices 1. In such a case, the semiconductor light emitting devices 1 may be singulated using blade dicing and the like.

According to the method for manufacturing the semiconductor light emitting device 1 according to this embodiment, for example, the thickness of the resin 43 into which the fluorescer 41 is mixed is adjusted to the target thickness by adjusting the distance from the flat plate 201 to the first major surface 25, the substrate 220, etc. Then, the wavelength conversion unit 40 that is adjusted to the target thickness is formed by curing the resin 43 into which the fluorescer 41 is mixed. Therefore, the fluctuation of the thickness dimension of the wavelength conversion unit 40 can be suppressed. Thereby, the fluctuation of the chromaticity of the white light in the surface of the wafer 10 can be suppressed; and the chromaticity shift in the surface of the wafer 10 can be suppressed.

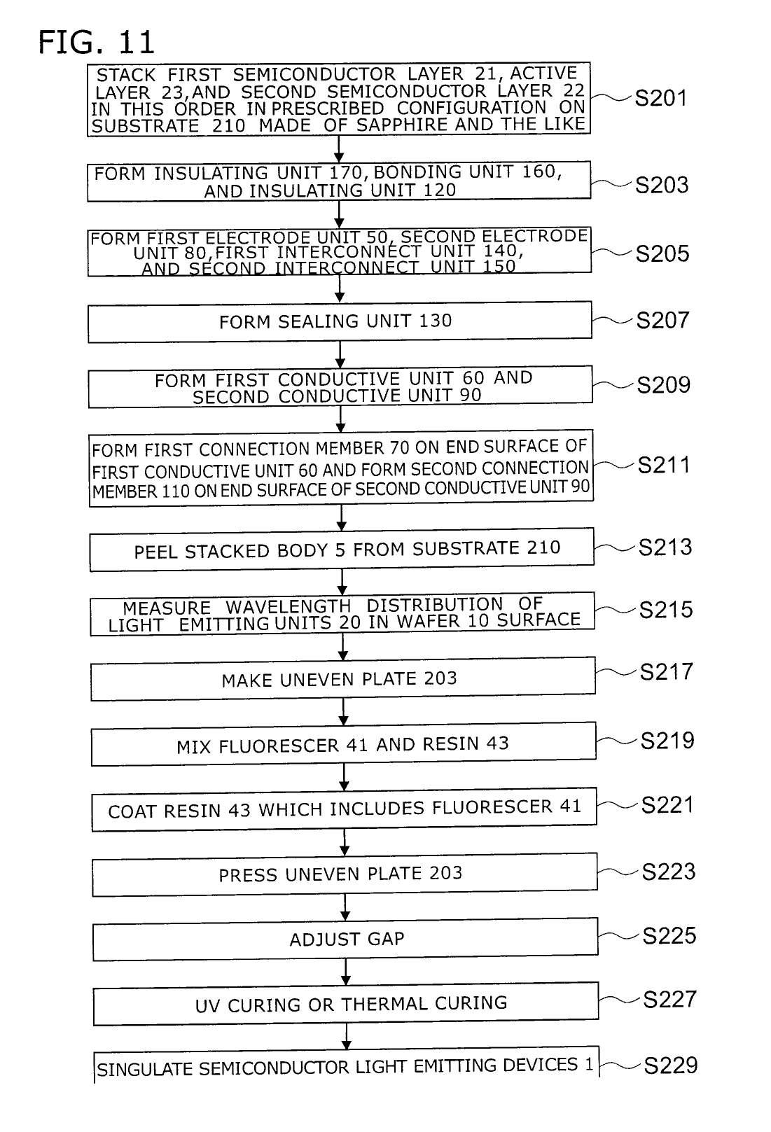

FIG. 11 is a flowchart illustrating a method for manufacturing the semiconductor light emitting device according to another embodiment of the invention.

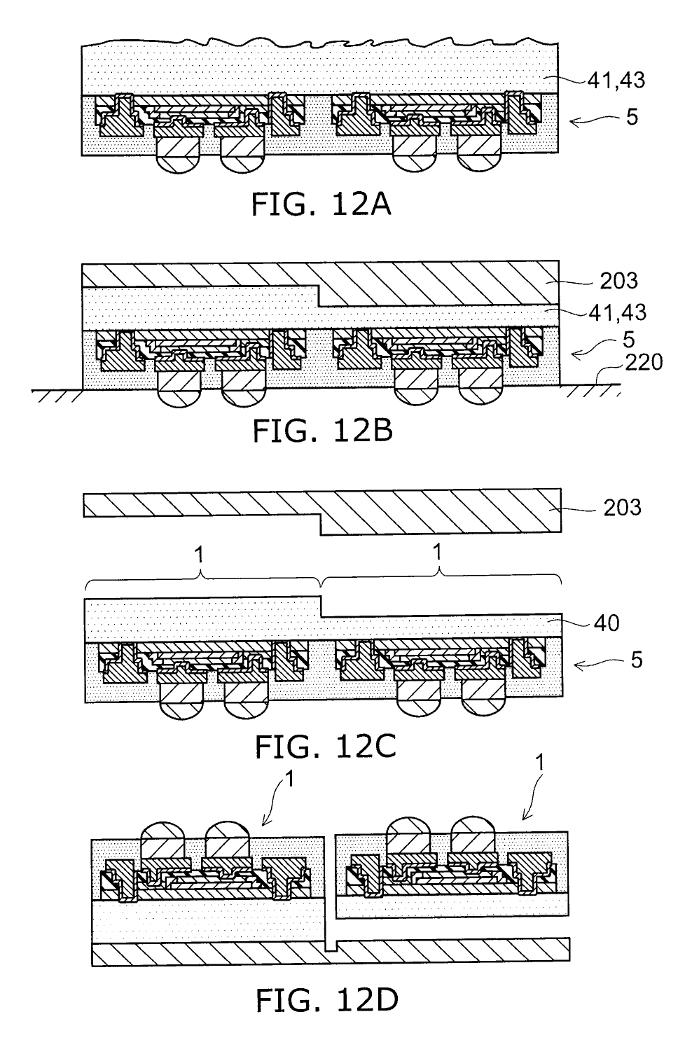

FIG. 12A to FIG. 12D are schematic cross-sectional views illustrating the method for manufacturing the semiconductor light emitting device according to this embodiment.

The method for manufacturing the semiconductor light emitting device according to this embodiment is a method for manufacturing that adjusts the thicknesses of the wavelength conversion units 40 of the multiple semiconductor light emitting devices 1 collectively formed on the wafer 10 based on the wavelength and the intensity of the light emitted from the light emitting unit 20. In this embodiment, the case where the thicknesses of the wavelength conversion units 40 of the multiple semiconductor light emitting devices 1 collectively formed on the wafer 10 are adjusted based on the wavelength distribution in the surface of the wafer 10 of the light emitted from the light emitting unit 20 is described as an example.

First, the manufacturing processes of step S201 to S213 illustrated in FIG. 11 are similar to the manufacturing processes of step S101 to S113 described above in regard to FIG. 7.

Then, the wavelength distribution in the surface of the wafer 10 of the light emitted from the light emitting unit 20 is measured (step S215). In such a case, for example, the wavelength of the PL (Photoluminescence) is measured by photoluminescence spectroscopy. Alternatively, for example, the wavelength of the light emitted from the light emitting unit 20 is measured by providing a current to the multiple light emitting units 20 collectively formed on the wafer 10. Thus, a wavelength distribution such as, for example, that illustrated in FIG. 3 is obtained by mapping the measured wavelength in the surface of the wafer 10. Although the case of measuring the wavelength distribution is illustrated in FIG. 11, the invention is not limited thereto. Instead of the wavelength distribution, the distribution of the light emission intensity may be measured.

Then, an uneven plate (a printing plate) 203 that is configured to be pressed onto the wavelength conversion unit (the resin in which the fluorescer is mixed) in the manufacturing process is made based on the measurement results of the wavelength distribution in the surface of the wafer 10 of the light emitted from the light emitting unit 20 (step S217). The uneven plate 203 is formed of metal, quartz, or a transparent resin. The transparent resin is a resin capable of transmitting at least UV of a wavelength not more than 405 nm. For example, the uneven plate 203 is made by performing laser patterning and the like based on the measurement results (the mapping data, etc.) of the wavelength distribution in the surface of the wafer 10 of the light emitted from the light emitting unit 20.

As an example, the patterning depth of the uneven plate 203 is adjusted by adjusting the applied voltage of the laser patterning apparatus based on the mapping data of the wavelength distribution in the surface of the wafer 10. Thereby, the height of the uneven plate 203 is adjusted based on the mapping data of the wavelength distribution in the surface of the wafer 10. Then, the pressing amount of the uneven plate 203 onto the wavelength conversion unit 40 is adjusted.

Then, as illustrated in FIG. 12A, the fluorescer 41 and the resin 43 of the wavelength conversion unit 40 are mixed (step S219); and the resin 43 into which the fluorescer 41 is mixed with a prescribed proportion is coated onto the first major surface 25 side of the light emitting unit 20 (step S221).

The manufacturing processes of step S219 and S221 are similar to the manufacturing processes of step S115 and S117 described above in regard to FIG. 7.

Continuing as illustrated in FIG. 12B, the uneven plate 203 made in step S217 is pressed onto the resin 43 (including the fluorescer 41) coated onto the first major surface 25 side of the light emitting unit 20 (step S223). Then, the thickness of the resin 43 into which the fluorescer 41 is mixed is adjusted to the target thickness by adjusting the distance from the uneven plate 203 to the first major surface 25 of the light emitting unit 20 (step S225). Alternatively, for example, the thickness of the resin 43 into which the fluorescer 41 is mixed is adjusted to the target thickness by adjusting the distance from the uneven plate 203 to the substrate 220 on which the stacked body 5 is placed (step S225). Alternatively, the thickness of the resin 43 into which the fluorescer 41 is mixed may be adjusted to the target thickness by adjusting the distance from the uneven plate 203 to a major surface or substrate that is different from the first major surface 25 and the substrate 220.

Continuing, the wavelength conversion unit 40 is formed by curing the resin 43 including the fluorescer 41 by irradiating ultraviolet (UV) onto the resin 43 including the fluorescer 41 or by heating the resin 43 including the fluorescer 41 (step S227). The manufacturing process of step S227 is similar to the manufacturing process of step S123 described above in regard to FIG. 7.

Then, as illustrated in FIG. 12C, the uneven plate 203 is peeled from the collectively-formed multiple semiconductor light emitting devices 1.

Continuing as illustrated in FIG. 12D, the semiconductor light emitting devices 1 are singulated (step S229). The manufacturing process of step S229 is similar to the manufacturing process of step S125 described above in regard to FIG. 7.

According to the method for manufacturing the semiconductor light emitting device 1 according to this embodiment, the uneven plate 203 is made based on the wavelength distribution in the surface of the wafer 10 of the light emitted from the light emitting unit 20; and the uneven plate 203 is pressed onto the resin 43 into which the fluorescer 41 is mixed. Then, the resin 43 into which the fluorescer 41 is mixed is cured. Thereby, the thicknesses of the wavelength conversion units 40 of the multiple semiconductor light emitting devices 1 collectively formed on the wafer 10 are adjusted based on the wavelength of the light emitted from the light emitting unit 20. Thereby, the fluctuation of the chromaticity of the white light in the surface of the wafer 10 can be suppressed; and the chromaticity shift in the surface of the wafer 10 can be suppressed.

For example, as illustrated in FIG. 4, the chromaticity (Cy) of the white light is larger at the portions of the surface of the wafer 10 where the wavelength of the light emitted from the light emitting unit 20 is shorter. Therefore, the patterning depth of the portions of the uneven plate 203 are set to be shallower by adjusting the applied voltage of the laser patterning apparatus for the resin 43 (including the fluorescer 41) at the portions of the surface of the wafer 10 where the wavelength of the light emitted from the light emitting unit 20 is shorter. In such a case, the pressing amount of the uneven plate 203 is greater for the resin 43 (including the fluorescer 41) coated onto the portions of the surface of the wafer 10 where the wavelength of the light emitted from the light emitting unit 20 is shorter. Therefore, the thickness of the wavelength conversion unit 40 becomes thinner at the portions of the surface of the wafer 10 where the wavelength of the light emitted from the light emitting unit 20 is shorter. As illustrated in FIG. 5, the chromaticity (Cy) of the white light decreases as the thickness of the wavelength conversion unit 40 becomes thinner. Thereby, the fluctuation of the chromaticity of the white light in the surface of the wafer 10 can be suppressed even in the case where the wavelength of the light emitted from the light emitting unit 20 fluctuates in the surface of the wafer 10.

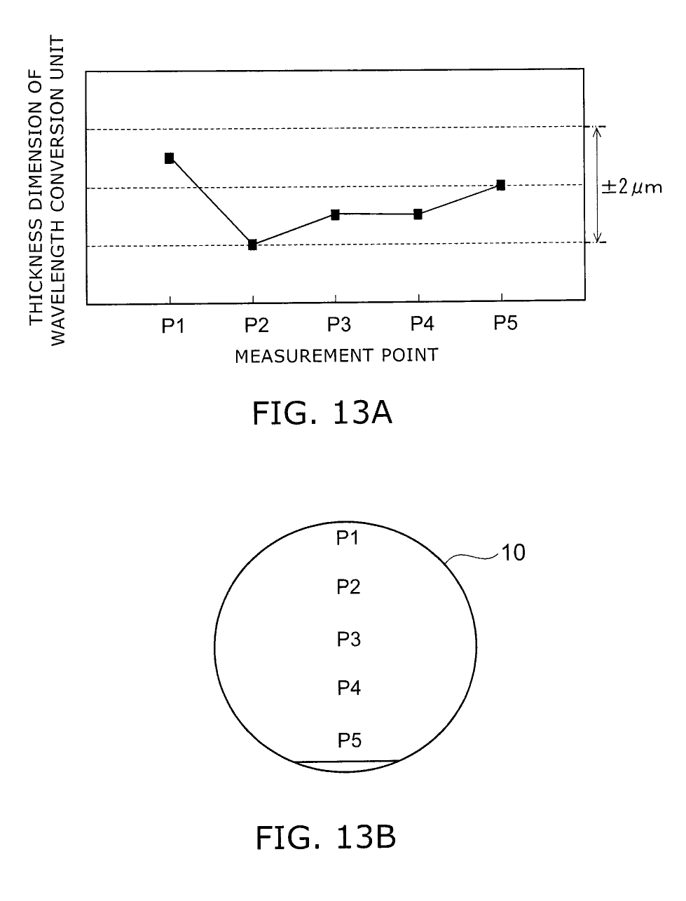

FIG. 13A and FIG. 13B are schematic views illustrating the thickness dimension of the wavelength conversion unit formed by the method for manufacturing the semiconductor light emitting device according to this embodiment.

FIG. 13A is a graph illustrating an example of the thickness dimension of the wavelength conversion unit formed by the method for manufacturing the semiconductor light emitting device according to this embodiment. FIG. 13B is a schematic plan view illustrating measurement points in the surface of the wafer 10.

As illustrated in FIG. 13A, the fluctuation of the thickness dimension of the wavelength conversion unit 40 formed by the method for manufacturing the semiconductor light emitting device 1 according to this embodiment is within about ±2 μm for the measurement points P1 to P5 in the surface of the wafer 10. According to the experimental results illustrated in FIG. 5, the change ΔCy of the chromaticity Cy of the white light is about 0.005 in the case where the fluctuation of the thickness dimension of the wavelength conversion unit 40 is within about ±2 μm. According to knowledge obtained by the inventor, in the case where the change ΔCy of the chromaticity Cy of the white light is about 0.005, the chromaticity shift substantially is not perceived by human vision; and individual differences (the fluctuation of the light emission characteristics of the wavelength, the intensity, and the like of the light) of the light emitting unit 20 can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light emitting device wafer including a plurality of semiconductor light emitting devices, the plurality of semiconductor light emitting devices being collectively formed, the wafer comprising:
a light emitting unit having a first major surface and a second major surface on a side opposite to the first major surface; and
a wavelength conversion unit provided on the first major surface side, the wavelength conversion unit containing a fluorescer,
a thickness of the wavelength conversion unit changing based on a distribution in a surface of the wafer of at least one selected from a wavelength and an intensity of light emitted from the light emitting unit of the plurality of semiconductor light emitting devices.

2. A method for manufacturing a semiconductor light emitting device including collectively forming a plurality of semiconductor light emitting devices on a wafer, the method comprising:
forming a plurality of light emitting units on the wafer, the plurality of light emitting units having a first major surface and a second major surface configured to be a surface opposite to the first major surface; and
forming a wavelength conversion unit by coating a medium onto the first major surface side, subsequently adjusting a thickness of the medium by adjusting a distance between the first major surface and a printing plate, and curing the medium, a fluorescer being mixed in the medium, the printing plate being configured to be pressed onto the medium, the wavelength conversion unit having the adjusted thickness.

3. The method according to claim 2, wherein the printing plate is a flat plate.

4. The method according to claim 2, wherein the printing plate is an uneven plate made based on a wavelength distribution in a surface of the wafer of light emitted from the plurality of light emitting units.

5. The method according to claim 2, wherein:
the printing plate is formed of metal, quartz, or a transparent resin; and
the transparent resin is a resin capable of transmitting at least ultraviolet of a wavelength not more than 405 nanometers.

6. The method according to claim 2, wherein the collectively-formed plurality of semiconductor light emitting devices is further singulated by using blade dicing.
